(19) United States
(12) Patent Application Publication
(10) Pub. No.: US 2017/0373084 A1
(43) Pub. Date: Dec. 28, 2017

(54) MEMORY DEVICE HAVING VERTICAL STRUCTURE

(71) Applicant: Samsung Electronics Co., Ltd., Suwon-si (KR)

(72) Inventors: Sang-won Shim, Seoul (KR); Bong-soon LIM, Seoul (KR)

(73) Assignee: Samsung Electronics Co., Ltd., Suwon-si (KR)

(21) Appl. No.: 15/429,474

(22) Filed: Feb. 10, 2017

(30) Foreign Application Priority Data
Jun. 27, 2016 (KR) 10-2016-0080245

(51) Int. Cl. H01L 27/11573; H01L 27/11565; H01L 23/528; H01L 27/11582; H01L 23/522

(52) U.S. Cl. CPC H01L 27/11573; H01L 27/11582; H01L 23/5226; H01L 23/528; H01L 27/11565

(57) ABSTRACT

A memory device includes a first semiconductor layer, a second semiconductor layer on the first semiconductor layer, and upper bit lines. The first semiconductor layer includes lower bit lines that extend in a first direction and are parallel to each other in a second direction perpendicular to the first direction, and a substrate. The second semiconductor layer includes vertical pillars extending in a third direction that is perpendicular to the first and second directions. The upper bit lines are connected to the vertical pillars and extend in the first direction on the second semiconductor layer. The upper bit lines are arranged to have a first pitch in the second direction. The lower bit lines are arranged to have a second pitch in the second direction. The first pitch and the second pitch have different lengths.

### CROSS-REFERENCE TO RELATED APPLICATION

This present application claims priority under 35 U.S.C. §119 to Korean Patent Application No. 10-2016-0080245, filed on Jun. 27, 2016, in the Korean Intellectual Property Office, the disclosure of which is incorporated herein in its entirety by reference.

### BACKGROUND

The present disclosure relates to a semiconductor device, and more particularly, to a layout of a connection region connecting a cell region of a memory device to a page buffer region thereof.

In order to satisfy high performance and inexpensive prices, the integration of memory devices may be increased. In particular, operations of memory devices and structures of operational circuits and/or interconnection lines have become more complicated due to the reduction in memory cell sizes for high integration of memory devices. Accordingly, a memory device having improved integration density and excellent electrical characteristics is desired.

### SUMMARY

Inventive concepts relate to a memory device having excellent electrical characteristics and high integration density.

According to some example embodiments of inventive concepts, a memory device includes a first semiconductor layer, a second semiconductor layer on the first semiconductor layer, and a plurality of upper bit lines. The first semiconductor layer includes a plurality of lower bit lines that extend in a first direction and are parallel to each other in a second direction perpendicular to the first direction. The first semiconductor layer includes a substrate. The second semiconductor layer includes a plurality of vertical pillars extending in a third direction that is perpendicular to the first and second directions. The plurality of upper bit lines are connected to the plurality of vertical pillars and extend in the first direction on the first semiconductor layer. The plurality of upper bit lines are arranged to have a first pitch in the second direction. The plurality of lower bit lines are arranged to have a second pitch in the second direction. The first pitch and the second pitch have different lengths.

According to some example embodiments of inventive concepts, a memory device includes a first semiconductor layer, a plurality of page buffer circuits in the first semiconductor layer and arranged in a plurality of groups, a second semiconductor layer on the first semiconductor layer, and a plurality of upper bit lines. The first semiconductor layer includes a plurality of lower bit lines extending in a first direction and arranged in a second direction perpendicular to the first direction. The first semiconductor layer includes a substrate. The plurality of page buffer circuits are in the first semiconductor layer and are arranged in a plurality of groups The second semiconductor layer is on the first semiconductor layer in a third direction perpendicular to the first and second directions and includes a plurality of vertical pillars and a plurality of gate structures. The plurality of gate structures include a plurality of gate conductive layers stacked along sidewalls of the plurality of vertical pillars. The plurality of upper bit lines are connected to the plurality of vertical pillars. The plurality of upper bit lines extend in the first direction on the plurality of gate structures and are arranged in the second direction. The plurality of upper bit lines are arranged to have a first pitch. The plurality of lower bit lines are arranged to have a second pitch. The second pitch is greater than the first pitch.

According to some example embodiments of inventive concepts, a memory device includes a substrate, a plurality of lower bit lines on the substrate, a memory cell array on the substrate over the plurality of bit lines, a plurality of word lines stacked on top of each other in a third direction crossing a first direction and a second direction, and a plurality of upper bit lines connected to the memory cell array. The plurality of lower bit lines extend in the first direction and are spaced apart from each other by a first distance in the second direction. The second direction crosses the first direction. The plurality of word lines extend in the second direction and are connected to the memory cell array. The plurality of upper bit lines cross over the word lines and extend in the first direction. The plurality of upper bit lines are spaced apart from each other in the second direction by a second distance that is less than the first distance.

### BRIEF DESCRIPTION OF THE DRAWINGS

Some example embodiments of inventive concepts will be more clearly understood from the following detailed description taken in conjunction with the accompanying drawings in which:

FIG. 1 is a block diagram of a memory device according to some example embodiments of inventive concepts;

FIG. 2 is a diagram schematically illustrating a structure of the memory device of FIG. 1, according to some example embodiments of inventive concepts;

FIG. 3 is a diagram illustrating an example of a memory cell array of FIG. 1, according to some example embodiments of inventive concepts;

FIG. 4 is a circuit diagram of an equivalent circuit of one of memory blocks of FIG. 3, according to some example embodiments of inventive concepts;

FIG. 5 is a plan view of a part of a vertical memory device according to some example embodiments of inventive concepts;

FIG. 6 is a perspective view corresponding to a part of the plan view of FIG. 5;

FIG. 7 is a cross-sectional view of the vertical memory device of FIG. 5;

FIG. 8 is a layout diagram of a memory device according to some example embodiments of inventive concepts;

FIGS. 9 and 10 are cross-sectional views of the memory device of FIG. 8;

FIG. 11 is a layout diagram of a part of a memory device according to some example embodiments of inventive concepts;

FIG. 12 is a cross-sectional view of a vertical memory device according to some example embodiments of inventive concepts;

FIG. 13 is a perspective view of a memory block of a vertical memory device according to some example embodiments of inventive concepts;

FIG. 14 is a diagram illustrating a configuration of circuits in a memory device according to some example embodiments of inventive concepts; and

FIG. 15 is a block diagram of a computing system including a memory system according to some example embodiments of inventive concepts.

### DETAILED DESCRIPTION

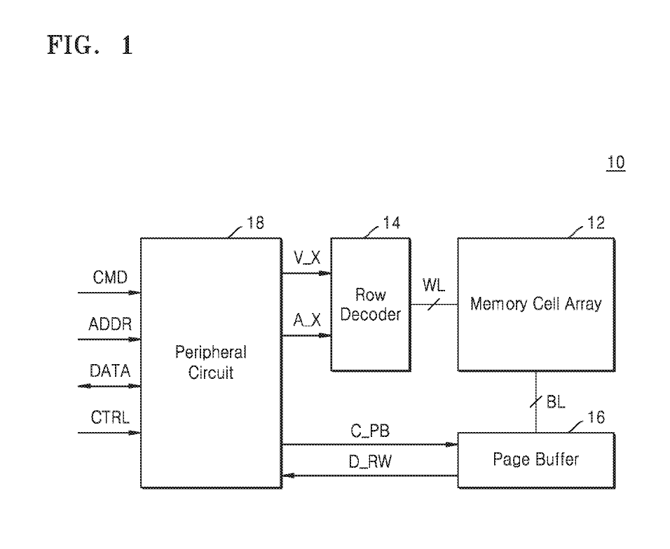

FIG. 1 is a block diagram of a memory device 10 according to some example embodiments of inventive concepts. As illustrated in FIG. 1, the memory device 10 may include a memory cell array 12, a row decoder 14, a page buffer 16, and a peripheral circuit 18.

The memory cell array 12 may include a plurality of memory cells, each having a state corresponding to stored data. The plurality of memory cells may be arranged in the memory cell array 12 and may be accessed through a plurality of word lines WL and a plurality of bit lines BL. The memory cells may be volatile memory cells where stored data is lost when supplied power is cut off or non-volatile memory cells where stored data is maintained even when supplied power is cut off. For example, when the memory cells are volatile memory cells, the memory device 10 may be dynamic random access memory (DRAM), static random access memory (SRAM), mobile DRAM, double data rate synchronous dynamic random access memory (DDR SDRAM), low power DDR (LPDDR) SDRAM, graphic DDR (GDDR) SDRAM, or Rambus dynamic random access memory (RDRAM). Also, when the memory cells are non-volatile memory cells, the memory device 10 may be electrically erasable programmable read-only memory (EEPROM), a flash memory, phase change random access memory (PRAM), resistance random access memory (RRAM), nano floating gate memory (NFGM), polymer random access memory (PoRAM), magnetic random access memory (MRAM), or ferroelectric random access memory (FRAM). Also, the memory device 10 may be a hybrid memory device in which the memory cell array 12 includes both of a volatile memory cell and a non-volatile memory cell. In the following description, the memory device 10 is described to be a vertical NAND flash device. However, inventive concepts are not limited thereto.

Referring to FIG. 1, the row decoder 14 may receive a drive voltage V_X and a row address A_X from the peripheral circuit 18 and control the word lines arranged in the memory cell array 12. For example, the row decoder 14 may activate at least one of the word lines based on the row address A_X and apply the drive voltage V_X to a selected word line. Memory cells selected by word lines activated by the row decoder 14 based on the row address A_X may be referred to as a page, and data may be written to the memory cell array 12 or read from the memory cell array 12 in units of pages.

The row decoder 14 may not only be disposed adjacent to the memory cell array 12, but also include identical circuits repeatedly arranged adjacent to the respective word lines arranged in the memory cell array 12. Accordingly, the row decoder 14 may have a length that is substantially the same as that of the memory cell array 12 in a direction in which the word lines are arranged, for example, in a direction perpendicular to a direction in which the word lines extend.

Referring to FIG. 1, the page buffer 16 may receive a page buffer control signal C_PB from the peripheral circuit 18 and transmit or receive a data signal D_RW to or from the peripheral circuit 18. The page buffer 16 may control the bit lines arranged in the memory cell array 12 in response to the page buffer control signal C_PB. For example, the page buffer 16 may sense a signal of a bit line in response to the page buffer control signal C_PB and thus detect data stored in a memory cell of the memory cell array 12 and may transmit the data signal D_RW to the peripheral circuit 18 according to the detected data. Also, the page buffer 16 may apply a signal to a bit line based on the data signal D_RW received from the peripheral circuit 18, in response to the page buffer control signal C_PB, and thus write data to a memory cell of the memory cell array 12. The page buffer 16, as described above, may write data to or read data from a memory cell connected to a word line activated by the row decoder 14.

The page buffer 16 may include a read circuit for performing a data read operation, a write circuit for performing a data write operation, and a plurality of latches for temporarily storing data. The read circuit, the write circuit, and the latches may be arranged at each bit line. Although not illustrated in FIG. 1, the page buffer 16 may include a column decoder and receive a column address from the peripheral circuit 18. When the page buffer 16 includes a column decoder, the read circuit, the write circuit, and the latches may be arranged at each output line of the column decoder, instead of being arranged in units of bit lines.

The page buffer 16 may not only be disposed adjacent to the memory cell array 12, but also include identical circuits repeatedly arranged adjacent to the respective bit lines arranged in the memory cell array 12. Accordingly, the page buffer 16 may have a length that is substantially the same as that of the memory cell array 12 in a direction in which the bit lines are arranged, for example, in a direction perpendicular to a direction in which the bit lines extend.

Referring to FIG. 1, the peripheral circuit 18 may receive a command signal CMD, an address signal ADDR, and a control signal CTRL from the outside of the memory device 10 and transmit or receive data DATA to or from an apparatus, for example, a memory controller, outside the memory device 10. The peripheral circuit 18 may output signals, for example, the row address A_X or the page buffer control signal C_PB, to write data to the memory cell array 12 or read data from the memory cell array 12, based on the command signal CMD, the address signal ADDR, and the control signal CTRL. The peripheral circuit 18 may include a plurality of sub-circuits. The sub-circuits of the peripheral circuit 18 may include a voltage generation circuit for generating various voltages, including the drive voltage V_X, needed for an operation of the memory device 10, and include an error correction circuit for correcting an error of data read from the memory cell array 12.

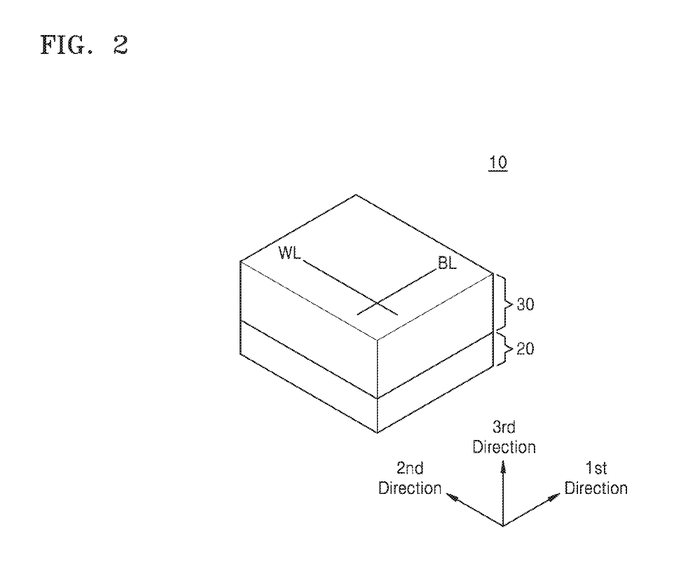

FIG. 2 schematically illustrates a structure of the memory device 10 of FIG. 1, according to some example embodiments of inventive concepts. As described above with reference to FIG. 1, the memory device 10 may include the memory cell array 12, the row decoder 14, the page buffer 16, and the peripheral circuit 18, and the elements of the memory device 10 may be formed in a semiconductor manufacturing process. FIG. 2 will be hereinafter described with reference to FIG. 1.

Referring to FIG. 2, the memory device 10 may include a first semiconductor layer 20 and a second semiconductor layer 30, and the second semiconductor layer 30 may be stacked on the first semiconductor layer 20 in a third direction. According to some example embodiments of inventive concepts, the row decoder 14, the page buffer 16, and the peripheral circuit 18 of FIG. 1 may be formed in the first semiconductor layer 20, and the memory cell array 12 of FIG. 1 may be formed in the second semiconductor layer 30. In other words, the first semiconductor layer 20 may include a substrate, and semiconductor devices such as transistors and patterns for wiring devices may be formed on the substrate. Accordingly, circuits, for example, circuits corresponding to the row decoder 14, the page buffer 16, and the peripheral circuit 18 may be formed in the first semiconductor layer 20.

After the circuits are formed in the first semiconductor layer 20, the second semiconductor layer 30 including the memory cell array 12 may be formed, and patterns for electrically connecting the memory cell array 12 (e.g., the word lines WL and the bit lines BL) to the circuits (e.g., circuits corresponding to the row decoder 14 and the page buffer 16) formed in the first semiconductor layer 20 may be formed. Accordingly, the memory device 10 may have a structure, that is, a Cell-On-Peri or Cell-Over-Peri (COP) structure, in which the memory cell array 12 and other circuits (e.g., the circuits corresponding to the row decoder 14, the page buffer 16, and the peripheral circuit 18) are disposed in a stacking direction, that is, the third direction. As circuits, except for the memory cell array 12, are disposed under the memory cell array 12, the COP structure may effectively decrease an area that is occupied on a surface perpendicular to the stacking direction. Accordingly, the number of memory cells that are integrated in the memory device 10 may be increased.

As illustrated in FIG. 2, in the second semiconductor layer 30 where the memory cell array 12 is formed, the word lines WL may extend in the second direction perpendicular to the stacking direction, that is, the third direction. The bit lines BL may extend in the first direction perpendicular to the stacking direction, that is, the third direction. As described above, the memory cells included in the memory cell array 12 may be accessed through the word lines WL and the bit lines BL, and the word lines WL and the bit lines BL may be electrically connected to the circuits formed in the first semiconductor layer 20, for example, the circuits corresponding to the row decoder 14 and the page buffer 16.

Although not illustrated in FIG. 2, a plurality of pads for electrical connection to the outside of the memory device 10 may be disposed in the memory device 10. For example, a plurality of pads for the command signal CMD, the address signal ADDR, and the control signal CTRL received from the apparatus, for example, a memory controller, outside the memory device 10, and a plurality of pads for inputting/outputting data DATA may be disposed. The pads may be disposed adjacent to each other in a vertical direction, that is, the third direction, or a horizontal direction, that is, the second direction, with respect to the peripheral circuit 18 that processes a signal received from the outside of the memory device 10 or a signal that is transmitted to the outside of the memory device 10.

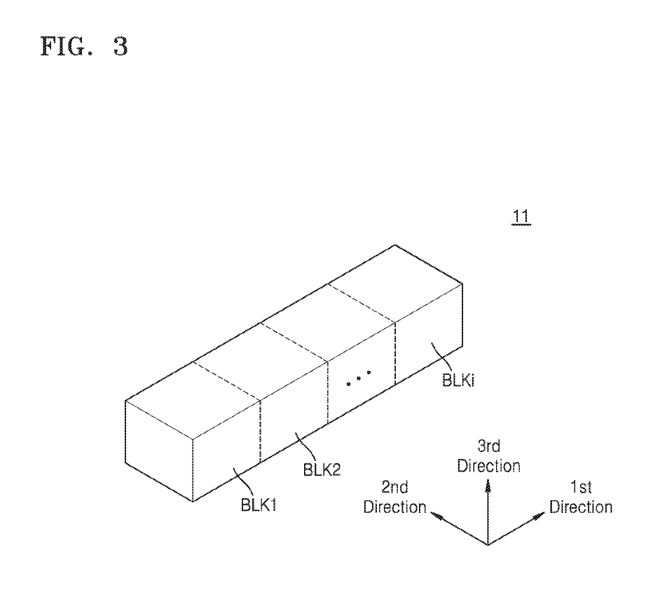

FIG. 3 illustrates an example of the memory cell array 12 of FIG. 1, according to some example embodiments of inventive concepts. Referring to FIG. 3, a memory cell array 11 that is an example of the memory cell array 12 may include a plurality of memory blocks BLK1 to BLKi.

Each of the memory blocks BLK1 to BLKi may have a three-dimensional (3D) structure or a vertical structure. In detail, each of the memory blocks BLK1 to BLKi may include structures extending in the first and second directions. In addition, each of the memory blocks BLK1 to BLKi may include a plurality of NAND strings extending in the third direction. The plurality of NAND strings may be provided by being separated by a particular distance in the first and second directions.

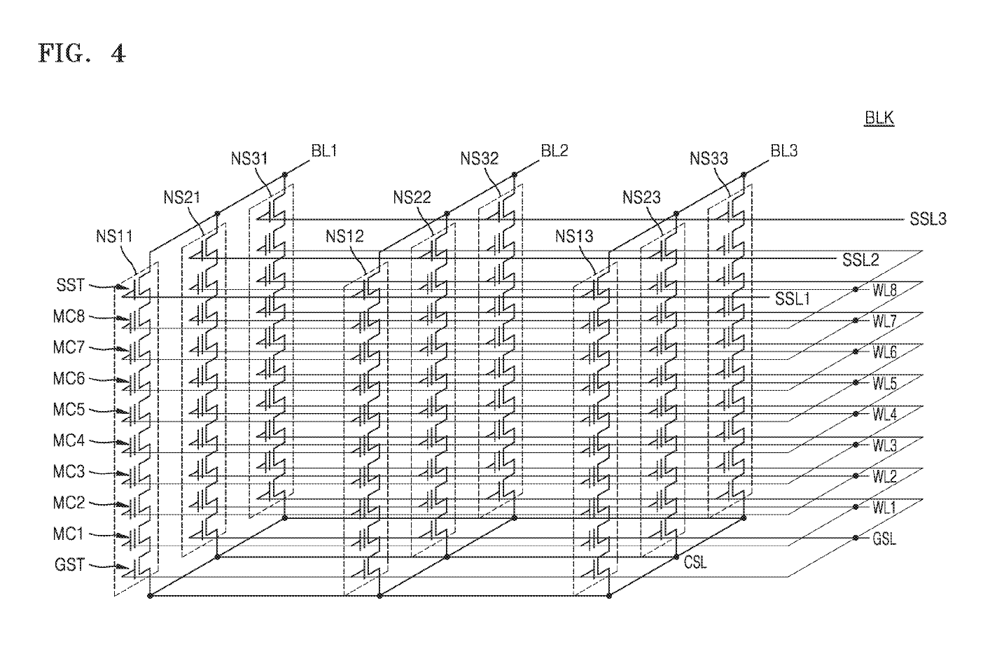

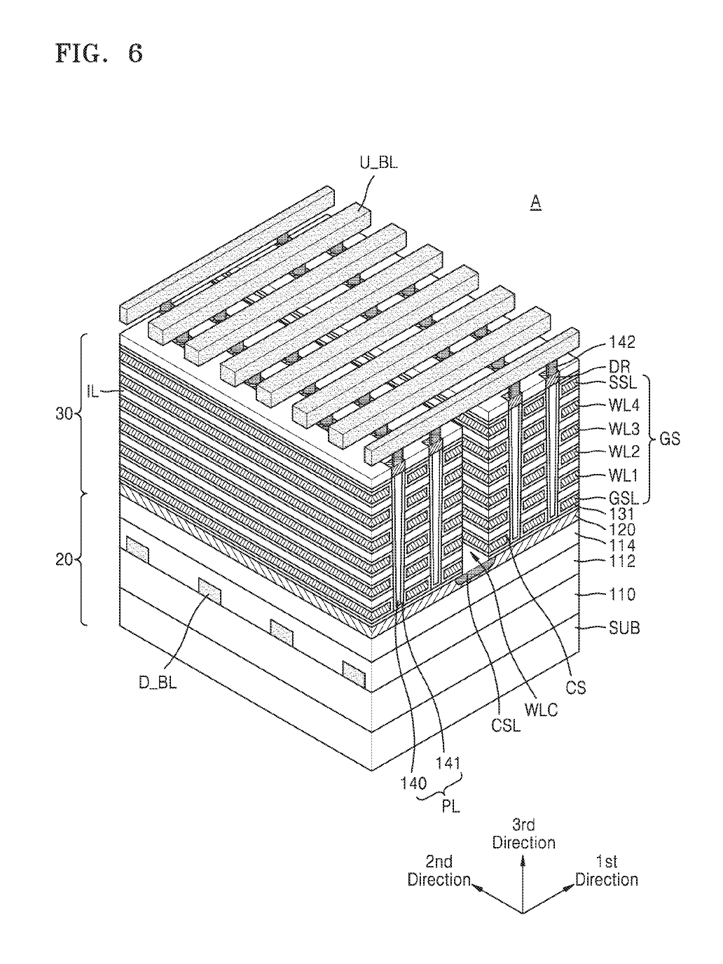

Each of the NAND strings may be connected to a bit line BL, a string selection line SSL (refer to FIG. 6), a ground selection line GSL (refer to FIG. 6), word lines WL, and a common source line CSL (refer to FIG. 6). In other words, each of the memory blocks BLK1 to BLKi may be connected to a plurality of bit lines BL, a plurality of string selection lines SSL (refer to FIG. 6), a plurality of ground selection lines GSL (refer to FIG. 6), a plurality of word lines WL, and a common source line CSL (refer to FIG. 6). The memory blocks BLK1 to BLKi are described in more detail with reference to FIG. 4.

FIG. 4 is a circuit diagram of a memory block BLK that corresponds to the memory blocks BLK1 to BLKi of FIG. 3, according to some example embodiments of inventive concepts.

Referring to FIG. 4, the memory block BLK may be a NAND flash memory having a vertical structure. The memory blocks BLK1 to BLKi of FIG. 3 may be implemented as in FIG. 4. The memory block BLK may include a plurality of NAND strings NS11 to NS33, a plurality of word lines WL1 to WL8, a plurality of bit lines BL1 to BL3, a ground selection line GSL, a plurality of string selection lines SSL1 to SSL3, and a common source line CSL. The number of NAND strings, the number of word lines, the number of bit lines, the number of ground selection lines, and the number of string selection lines may be variously changed according to various example embodiments of inventive concepts.

A plurality of NAND strings may be provided between each of the bit lines BL1 to BL3 and the common source line CSL. The NAND strings NS11, NS21, and NS31 may be provided between the bit line BL1, which is a first bit line, and the common source line CSL. The NAND strings NS12, NS22, and NS32 may be provided between the bit line BL2, which is a second bit line. The common source line CSL and the NAND strings NS13, NS23, and NS33 may be provided between the bit line BL3, which is a third bit line, and the common source line CSL. Hereinafter, the NAND string may be referred to as a string for convenience.

Strings commonly connected to one bit line may form one column. For example, the strings NS11, NS21, and NS31 commonly connected to the first bit line BL1 may correspond to a first column, the strings NS12, NS22, and NS32 commonly connected to the second bit line BL2 may correspond to a second column, and the strings NS13, NS23, and NS33 commonly connected to the third bit line BL3 may correspond to a third column.

Strings connected to one string selection line may form one row. For example, the strings NS11, NS12, and NS13 connected to the string selection line SSL1 that is a first string selection line may correspond to a first row, the strings NS21, NS22, and NS23 connected to the string selection line SSL2 that is a second string selection line may correspond to a second row, and the strings NS31, NS32, and NS33 connected to the string selection line SSL3 that is a third string selection line may correspond to a third row.

In each string, the string selection transistor SST is connected to one of the string selection lines SSL1, SSL2, and SSL3. In each string, a plurality of memory cells MC1 to MC8 are connected to the word lines WL1 to WL8, respectively. In each string, the ground selection transistor GST is connected to the ground selection line GSL. In each string, the string selection transistor SST is connected to one of the bit lines BL1, BL2, and BL3 and the ground selection transistor GST is connected to the common source line CSL.

Word lines (e.g., first word line WL1) of the same height are connected in common to each other, and the string selection lines SSL1 to SSL3 are separated from each other. The first word line WL1 and the first string selection line SSL1 are selected to program memory cells that are connected to the first word line WL1 and belong to the strings NS11, NS12, and NS13.

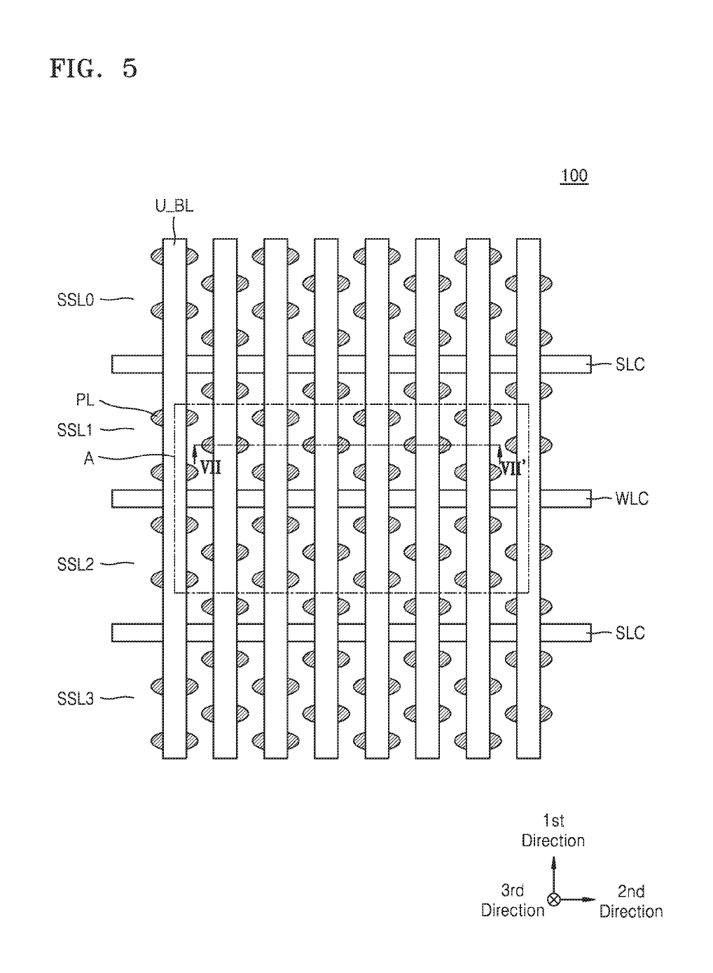

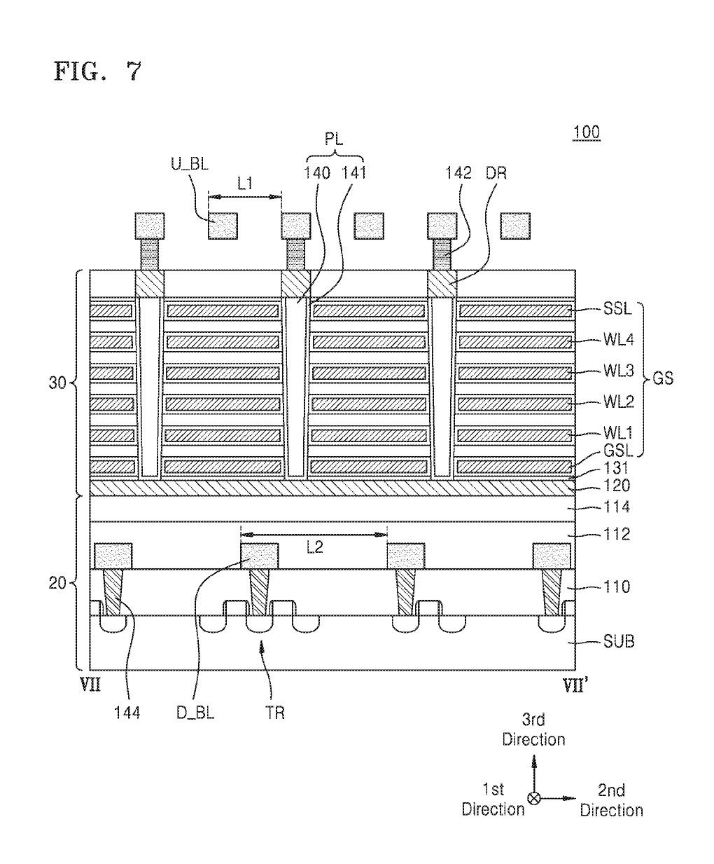

FIG. 5 is a plan view of a part of a vertical memory device 100 according to some example embodiments of inventive concepts. FIG. 6 is a perspective view of a part A of the plan view of FIG. 5. FIG. 7 is a cross-sectional view of the memory device 100, taken along a line VII-VII′ of FIG. 5. Referring to FIGS. 5 to 7, 3D structures extending in the first to third directions are provided.

Referring to FIG. 5, a plurality of upper bit lines U_BL extending in the first direction and a plurality of string selection lines SS0 to SS3 extending in the second direction may be arranged crossing each other. The plurality of string selection lines SS0 to SS3 may be separated from each other by a selection line cut region SLC or a word line cut region WLC.

As illustrated in FIGS. 6 and 7, a first semiconductor layer 20 where the row decoder 14, the page buffer 16, and the peripheral circuit 18 are formed may include a substrate SUB and first, second, and third interlayer insulating films 110, 112, and 114 sequentially stacked on the substrate SUB in the third direction in this stated order. The substrate SUB may have a main surface extending in the first direction and the second direction. In some example embodiments, the substrate SUB may include a polysilicon substrate, a silicon-on-insulator (SOI) substrate, or a germanium-on-insulator (GeOI) substrate.

As stated above, the first, second, and third interlayer insulating films 110, 112, and 114 may be sequentially stacked on the substrate SUB in this stated order. The first to third interlayer insulating layers 110, 112, and 114 may be formed by using an insulation material such as a silicon oxide through a chemical vapor deposition (CVD) process or a spin coating process.

A plurality of semiconductor devices, for example, transistors TR, may be formed on the substrate SUB of the first semiconductor layer 20. The semiconductor devices may be electrically connected to lower bit lines D_BL, formed in the second interlayer insulating film 112, via second contact plugs 144 penetrating through the first interlayer insulating film 110. In some example embodiments, lower bit line pads (not shown) for electrically connecting the lower bit lines D_BL to the upper bit lines U_BL may be formed in the third interlayer insulating film 114. For example, the semiconductor devices formed in the first semiconductor layer 20 may form a circuit corresponding to the page buffer 16 of FIG. 1.

As illustrated in FIGS. 6 and 7, a second semiconductor layer 30 where the memory cell array 12 of FIG. 1 is formed may be stacked on the first semiconductor layer 20 and may include a base layer 120 and gate structures GS on the base layer 120.

The base layer 120 may be a layer of a first conductive type, for example, p-type. A common source line CSL doped with impurities of a second conductive type, for example, n-type, and extending in the second direction may be arranged in the base layer 120. In some example embodiments, the base layer 120 of the second semiconductor layer 30 may be formed by using polysilicon through a sputtering process, a CVD process, an atomic layer deposition (ALD) process, or a physical vapor deposition (PVD) process. In some example embodiments, the base layer 120 of the second semiconductor layer 30 may be formed by forming an amorphous silicon layer on the third interlayer insulating layer 114 and then changing the amorphous silicon layer to a monocrystalline silicon layer via thermal treatment or laser beam irradiation. Accordingly, defects in the base layer 120 may be removed. In other example embodiments, the base layer 120 may be formed by a wafer bonding process. In this case, the base layer 120 may be formed by attaching a monocrystalline silicon wafer on the third interlayer insulating film 114 and then partially removing or planarizing an upper portion of the monocrystalline silicon wafer.

The gate structures GS may be formed on the base layer 120. A buffer dielectric film 131 may be formed between the base layer 120 and the gate structures GS. The buffer dielectric film 131 may be a silicon oxide film.

The gate structures GS may extend in the second direction. The gate structures GS may face each other in the first direction perpendicular to the second direction. The gate structures GS may include insulating films IL and gate electrodes GSL, WL1 to WL4, and SSL spaced apart from each other with the insulating films IL therebetween. The insulating films IL may be silicon oxide films. The buffer dielectric film 131 may be thinner than the insulating films IL. The gate electrodes GSL, WL1 to WL4, and SSL may include a doped silicon, a metal (e.g., tungsten), a metal nitride, a metal silicide, or a combination thereof.

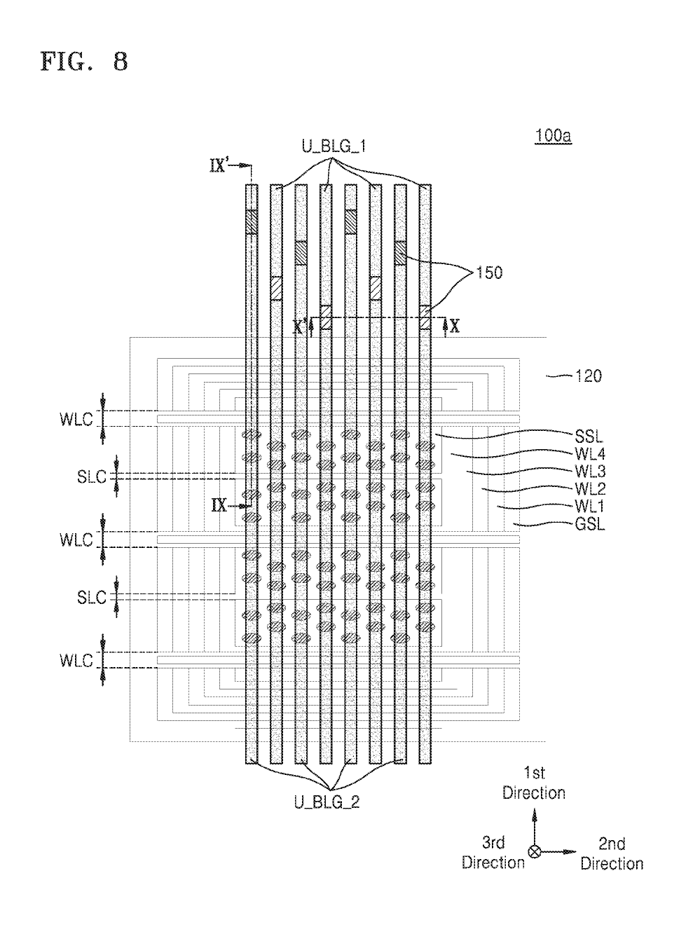

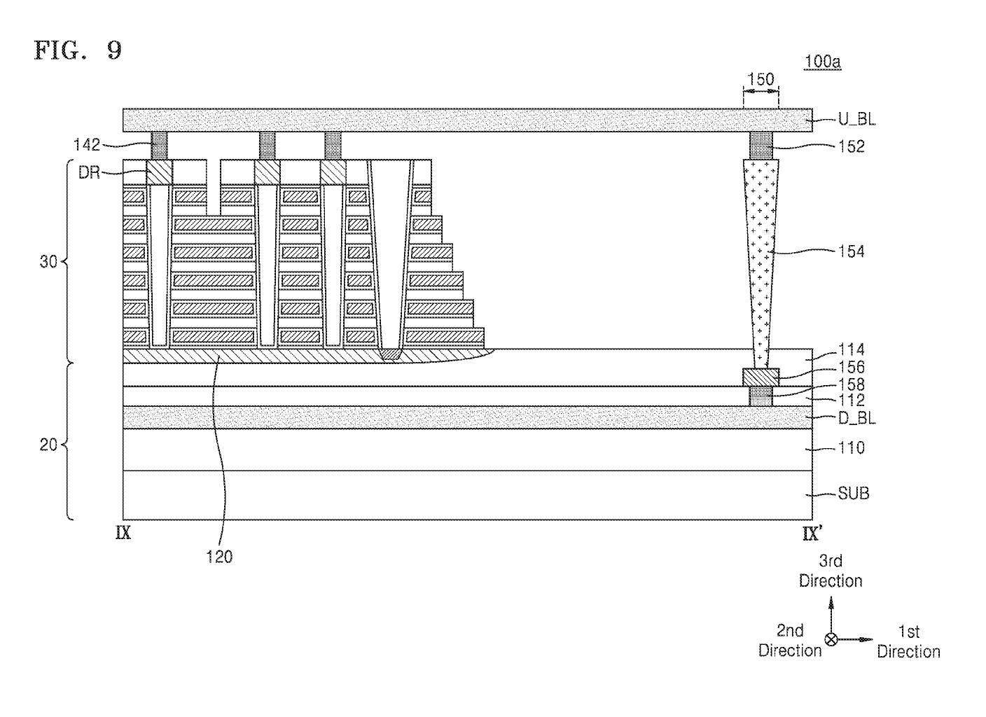

The gate electrodes GSL, WL1 to WL4, and SSL may include a ground selection line GSL, word lines WL1 to WL4, and a string selection line SSL. The ground selection line GSL, the word lines WL1 to WL4, and the string selection line SSL may be sequentially formed on the base layer 120 in the stated order. As a distance from the base layer 120 increases, the areas of the gate electrodes GSL, WL1 to WL4, and SSL may decrease. Referring to FIGS. 8 and 9, gate electrodes may be stacked in the form of stairs.

Although four word lines WL1 to WL4 are illustrated in FIGS. 6 and 7, a structure, in which a different number of word lines (e.g., 8, 16, 32, or 64 word lines) are stacked between the ground selection line GSL and the string selection line SSL in a vertical direction and the insulating films IL are respectively between every two adjacent word lines, may be formed. The number of word lines that are stacked between the ground selection line GSL and the string selection line SSL is not limited thereto. In addition, two or more ground selection lines GSL may be stacked in the vertical direction, and two or more string selection lines SSL may be stacked in the vertical direction.

The word line cut region WLC extending in the second direction may be disposed between the gate structures GS. The gate electrodes GSL, WL1 to WL4, and SSL may be separated from each other by the word line cut region WLC. For example, the word line cut region WLC may include an insulation material (e.g., silicon oxide) or may be an air gap.

A plurality of vertical pillars PL penetrating through the gate electrodes GSL, WL1 to WL4, and SSL and the insulating films IL in the third direction are arranged on a region of the base layer 120 where the gate structures GS are formed. The vertical pillars PL penetrate through the gate electrodes GSL, WL1 to WL4, and SSL and the insulating films IL and thus are connected to the base layer 120. The vertical pillars PL may have a long axis extending upward from the base layer 120, that is, extending in the third direction. First ends of the vertical pillars PL may be connected to the base layer 120, and second ends of the vertical pillars PL may be connected to the upper bit lines U_BL extending in the first direction. A surface layer 141 of each of the vertical pillars PL may include a silicon material of the second conductive type and may function as a channel region. The inside 140 of each of the vertical pillars PL may include an insulation material, such as a silicon oxide, or an air gap.

The vertical pillars PL may be formed in a honeycomb shape in which the vertical pillars PL cross vertical pillars PL of adjacent rows or columns. When the vertical pillars PL cross each other, a distance between adjacent vertical pillars PL may be relatively constant.

Each of the gate structures GS may include a charge storage layer CS. The charge storage layer CS may extend between the gate electrodes GSL, WL1 to WL4, and SSL and the insulating films IL and/or between the gate electrodes GSL, WL1 to WL4, and SSL and the vertical pillars PL. For example, the charge storage layer CS may have an oxide-nitride-oxide (ONO) structure.

Drains DR may be respectively disposed on the vertical pillars PL. For example, the drains DR may include a silicon material doped with impurities of the second conductive type. The upper bit lines U_BL extending in the first direction and spaced apart from each other by a particular distance in the second direction may be arranged on the drains DR. The upper bit lines U_BL may be connected to the drains DR via first contact plugs 142.

Referring to FIG. 7, the upper bit lines U_BL connected to the vertical pillars PL via the drains DR and the first contact plugs 142 have a first pitch L1, and the lower bit lines D_BL connected to the transistors TR, formed in the substrate SUB, via second contact plugs 144 have a second pitch L2. Although not illustrated in drawings, the upper bit lines U_BL may be electrically connected to the lower bit lines D_BL via contact plugs penetrating through the second semiconductor layer 30 and a portion of the first semiconductor layer 20.

The upper bit lines U_BL and the lower bit lines D_BL may be patterned by different processes. In some example embodiments, the upper bit lines U_BL may be patterned by using double patterning technology (DPT) or quadruple patterning technology (QPT) and the lower bit lines D_BL may be patterned by using spacer patterning technology (SPT). In this case, the second pitch L2 of the lower bit lines D_BL may be greater than the first pitch L1 of the upper bit lines U_BL. In some example embodiments, the second pitch L2 may be twice the first pitch L1. However, inventive concepts are not limited thereto.

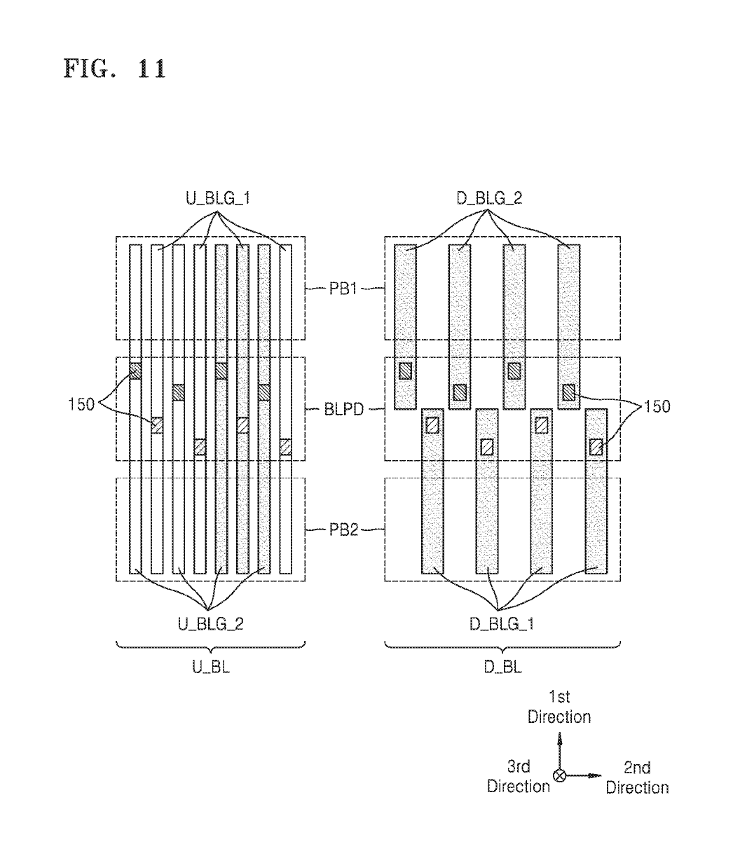

In some example embodiments, the lower bit lines D_BL may be grouped into a first lower bit line group and a second lower bit line group. Referring to FIG. 7, only lower bit lines D_BL corresponding to one of the first and second lower bit line groups are illustrated. Lower bit lines D_BL of a common group may be electrically connected to transistors TR of the common group. The transistors TR may form the page buffer 16 of FIG. 1. The lower bit lines D BL will be described in detail with reference to FIG. 11 later.

In some example embodiments, a page size in the vertical memory device 100 may increase by an increase in the number of upper bit lines U_BL that are selected by one string selection line SSL, compared to conventional vertical memory devices. Accordingly, program speed and read speed may be increased and the occurrence of disturbance may be reduced due to the reduction in the number of programs (NOPs).

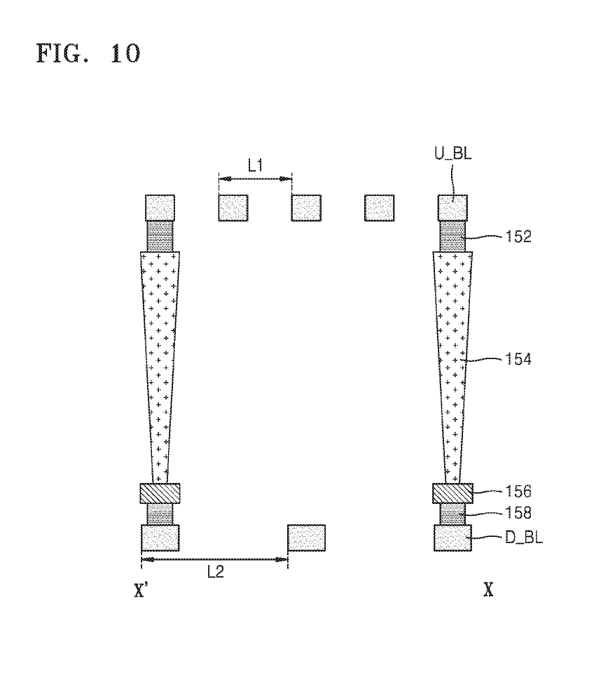

FIG. 8 is a layout diagram of a memory device 100a according to some example embodiments of inventive concepts, and FIGS. 9 and 10 are cross-sectional views of the memory device 100a. FIG. 9 is a cross-sectional view taken along a line IX-IX′ of FIG. 8, and FIG. 10 is a cross-sectional view taken along a line X-X′ of FIG. 8. In detail, FIGS. 8 to 10 illustrate an example of a structure for electrically connecting the upper bit lines U_BL formed on the second semiconductor layer 30 of FIG. 7 to the lower bit lines D_BL formed in the first semiconductor layer 20 of FIG. 7. FIGS. 8 to 10 will be descried with reference to FIGS. 1 and 2.

Referring to FIG. 8, a base layer 120 is provided, and gate electrodes GSL, WL1 to WL4, and SSL (a ground selection line GSL, word lines WL1 to WL4, and a string selection line SSL) may be sequentially formed vertically, that is, in the third direction, on the base layer 120 in the stated order. As a distance from the base layer 120 increases, the areas of the gate electrodes GSL, WL1 to WL4, and SSL may decrease. The gate electrodes GSL, WL1 to WL4, and SSL may be stacked in the form of stairs.

Vertical pillars PL may penetrate through the gate electrodes GSL, WL1 to WL4, and SSL and extend in the third direction. The vertical pillars PL may be arranged to be spaced part from each other by a desired (and/or alternatively predetermined) interval in the first direction and the second direction.

The upper bit lines U_BL, which extend in the first direction and are spaced apart from each other by a particular distance in the second direction and respectively overlap the vertical pillars PL in the third direction, may be arranged on the vertical pillars PL. Drains DR (refer to FIG. 9) may be respectively disposed on the vertical pillars PL, and the upper bit lines U_BL may be connected to the drains DR via first contact plugs 142 (refer to FIG. 9).

The upper bit lines U_BL may be grouped into a first upper bit line group U_BLG_1 and a second upper bit line group U_BLG_2. In some example embodiments, upper bit lines of the first upper bit line group U_BLG_1 and upper bit lines of the second upper bit line group U_BLG_2 may be alternately arranged in the second direction.

A connection region 150 of each of the upper bit lines U_BL may be defined in an outer portion thereof that does not overlap the base layer 120 vertically, that is, in the third direction. A conductive path that electrically connects the upper bit lines U_BL and the lower bit lines D_BL may be formed in the connection region 150.

Referring to FIG. 9, the first semiconductor layer 20 may include a substrate SUB and a plurality of interlayer insulating films, for example, first to third interlayer insulating films 110, 112, and 114, stacked in the third direction. Although not illustrated in FIGS. 8 to 10, a plurality of semiconductor devices, for examples, transistors, may be formed on the substrate SUB, and contract plugs for electrically connecting the lower bit lines D_BL to the semiconductor devices may be formed in the first interlayer insulating film 110.

The lower bit lines D_BL may be formed in the second interlayer insulating film 112. In some example embodiments, the lower bit lines D_BL may be grouped into a first lower bit line group and a second lower bit line group, and the first and second lower bit line group may be respectively connected to page buffers forming different page buffer groups. The lower bit lines D BL will be described in detail with reference to FIG. 11 later.

In the connection region 150, a conductive path may be formed between the upper bit lines U_BL and the lower bit lines D_BL through third contact plugs 154 penetrating through the second semiconductor layer 30 and a portion of the third interlayer insulating film 114. In other words, as illustrated in FIG. 9, the upper bit lines U_BL are electrically connected to the third contact plugs 154 via upper bit line contact plugs 152, and the lower bit lines D_BL are electrically connected to the third contact plugs 154 via lower bit line contact plugs 158 penetrating through a portion of the second interlayer insulating film 112 and lower bit line pads 156 formed in the third interlayer insulating film 114.

Referring to FIG. 10, a conductive path is formed between some of the upper bit lines U_BL including the first and second upper bit line groups U_BLG_1 and U_BLG_2 and some of the lower bit lines D_BL. In some example embodiments, all of the lower bit lines D_BL illustrated in FIG. 10 may be lower bit lines of the same group.

Referring to FIG. 10, the upper bit lines U_BL have a first pitch L1 and the lower bit lines D_BL have a second pitch L2. The upper bit lines U_BL and the lower bit lines D_BL may be patterned by different processes. In some example embodiments, the upper bit lines U_BL may be patterned by using a DPT or a QPT and the lower bit lines D_BL may be patterned by using an SPT. In this case, the second pitch L2 of the lower bit lines D_BL may be greater than the first pitch L1 of the upper bit lines U_BL. In some example embodiments, the second pitch L2 may be twice the first pitch L1. However, inventive concepts are not limited thereto.

In the memory device 100a having a vertical structure, in some example embodiments, a page size may increase by an increase in the number of upper bit lines U_BL that are selected by one string selection line SSL, compared to conventional vertical memory devices. Accordingly, program speed and read speed may be increased and the occurrence of disturbance may be reduced due to the reduction in the NOPs.

FIG. 11 is a layout diagram of upper bit lines U_BL and lower bit lines D_BL according to some example embodiments of inventive concepts. In detail, FIG. 11 illustrates an example of the arrangement of the upper bit lines U_BL and the lower bit lines D_BL of FIGS. 8 to 10. The upper bit lines U_BL may overlap the lower bit lines D_BL vertically, that is, in the third direction, and the upper bit lines U_BL and the lower bit lines D_BL are illustrated on the same plane for convenience of description. Although eight upper bit lines U_BL and eight lower bit lines D_BL are illustrated in FIG. 11, inventive concept are not limited thereto.

The upper bit lines U_BL may be spaced apart from each other by a particular distance in the second direction and extend in the first direction to overlap a first page buffer region PB1, a bit line pad region BLPD, and a second page buffer region PB2 vertically, that is, in the third direction. The upper bit lines U_BL may include a first upper bit line group U_BLG_1 and a second upper bit line groups U_BLG_2. Upper bit lines of the first upper bit line group U_BLG_1 and upper bit lines of the second upper bit line group U_BLG_2 may be alternately arranged.

The lower bit lines D_BL may include lower bit lines of a first lower bit line group D_BLG_1 and lower bit lines of a second lower bit line group D_BLG_2. The lower bit lines of the first lower bit line group D_BLG_1 may be spaced apart from each other by a particular distance in the second direction and overlap a portion of the bit line pad region BLPD and the second page buffer region PB2 vertically, that is, in the third direction. The lower bit lines of the second lower bit line group D_BLG_2 may be spaced apart from each other by a particular distance in the second direction and overlap the first page buffer region PB1 and a portion of the bit line pad region BLPD vertically, that is, in the third direction.

Page buffer circuits (not shown) forming a first page buffer group may be formed in the first page buffer region PB1, and page buffer circuits (not shown) forming a second page buffer group may be formed in the second page buffer region PB2. In some example embodiments, the page buffer circuits may be arranged together with peripheral circuits (not shown) and a memory cell array (not shown) in a stacking direction, that is, the third direction, thereby forming a COP structure. In the COP structure, the page buffer circuits and the peripheral circuits may be positioned under the lower bit lines D_BL and the upper bit lines U_BL may be positioned on the memory cell array. As the page buffer circuits and the peripheral circuits are arranged under the memory cell array, the COP structure may effectively reduce an area that is occupied on a surface perpendicular to the stacking direction.

A plurality of connection regions 150 where a conductive path between the upper bit lines U_BL and the lower bit lines D_BL is formed may be positioned in the bit line pad region BLPD. Connection regions 150 formed in upper bit lines of the first upper bit line group U_BLG_1 may overlap, in the third direction, connection regions 150 formed in lower bit lines of the first lower bit line group D_BLG_1. Connection regions 150 formed in upper bit lines of the second upper bit line group U_BLG_2 may overlap, in the third direction, connection regions 150 formed in lower bit lines of the second lower bit line group D_BLG_2.

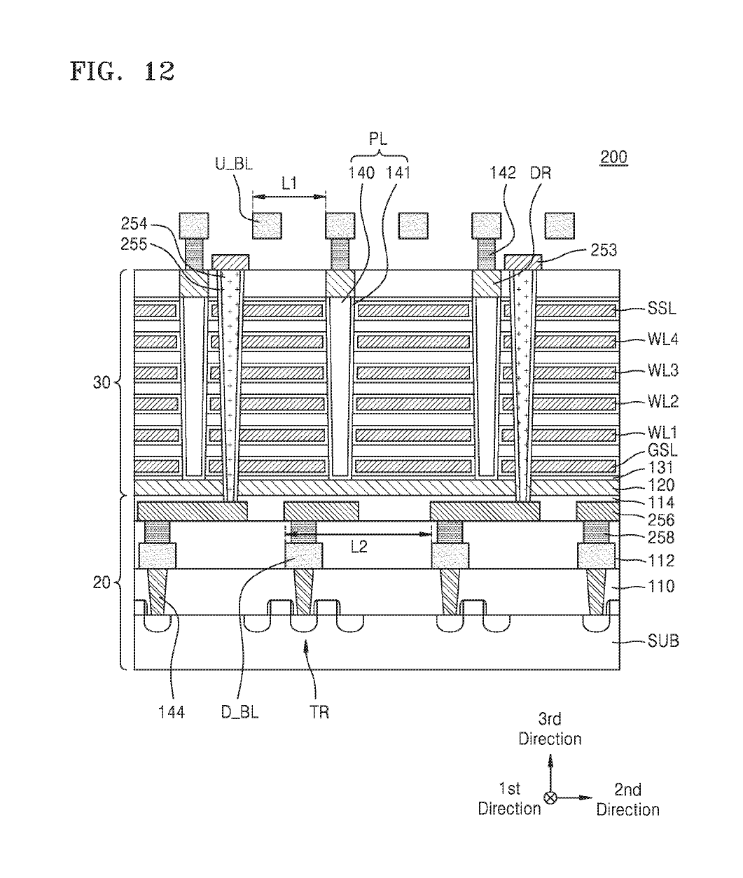

FIG. 12 is a cross-sectional view of a vertical memory device 200 according to some example embodiments of inventive concepts. In FIG. 12, elements that are the same as those of FIG. 7 are indicated by the same reference numerals as those of FIG. 7, and thus, repeated descriptions thereof are not provided.

Referring to FIG. 12, a conductive path may be formed between a first semiconductor layer 20 and a second semiconductor layer 30 through a third contact plug 254 formed by penetrating through a plurality of word lines WL1 to WL4 between vertical pillars PL. As illustrated in FIG. 12, the third contact plug 254 and an insulating film pattern 255 may be formed by penetrating through a string selection line SSL, the word lines WL1 to WL4, and a ground selection line GSL. The third contact plug 254 penetrating through the second semiconductor layer 30 may electrically connect an upper bit line pad 253 formed on the upper surface of the second semiconductor layer 30 and a lower bit line pad 256 formed in the first semiconductor layer 10.

Although not illustrated in FIG. 12, upper bit line pads 253 may be electrically connected to upper bit lines U_BL. In addition, lower bit line pads 256 may be electrically connected to lower bit lines D_BL via lower bit line contacts 258. Accordingly, the upper bit lines U_BL may be connected to the lower bit lines D_BL, formed in the first semiconductor device 20, via the third contact plug 254 formed by penetrating the word lines WL1 to WL4.

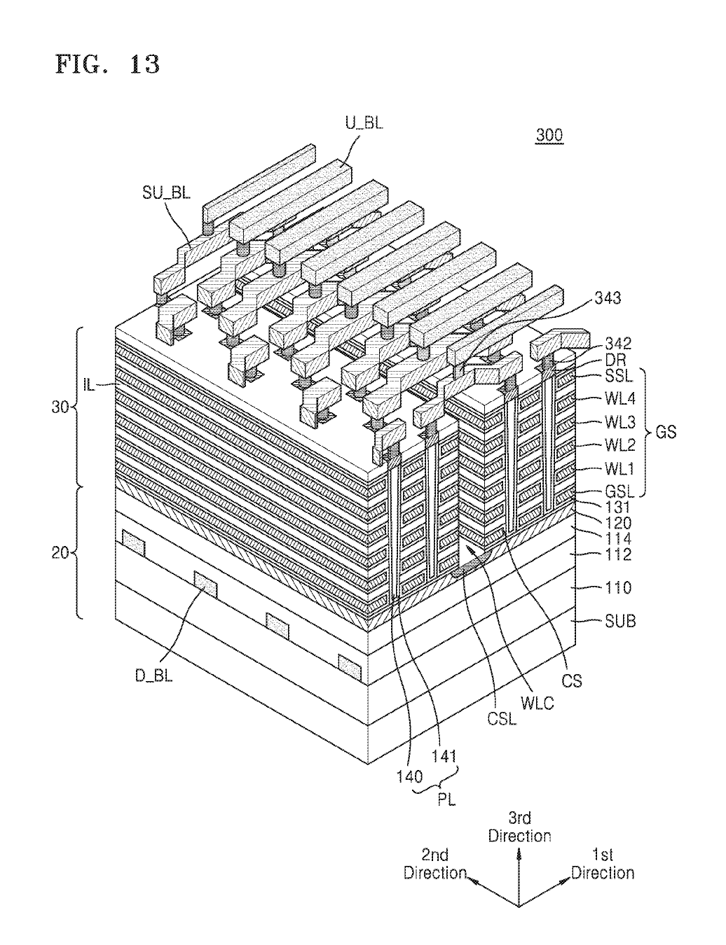

FIG. 13 is a perspective view of a memory block of a vertical memory device 300 according to some example embodiments of inventive concepts. In FIG. 13, elements having the same forms as those of FIG. 6 are indicated by the same reference numerals as those of FIG. 6, and thus, repeated descriptions thereof are not provided.

Referring to FIG. 13, auxiliary interconnection lines SU_BL are provided between vertical pillars PL and upper bit lines U_BL. The vertical pillars PL may be connected to the auxiliary interconnection lines SU_BL via first contact plugs 342. Each of the auxiliary interconnection lines SU_BL may connect two vertical pillars PL, coupled to different gate structures GS adjacent to each other, to each other via the first contact plugs 342.

Each of the auxiliary interconnection lines SU_BL may have a protruding portion protruding in the second direction or a direction opposite to the second direction. Auxiliary interconnection lines SU_BL each having a protruding portion protruding in the second direction and auxiliary interconnection lines SU_BL each having a protruding portion protruding in the direction opposite to the second direction may be alternately arranged in the first direction. Auxiliary interconnection line contact plugs 343 may be respectively disposed on the protruding portions of the auxiliary interconnection lines SU_BL. The upper bit lines U_BL may be connected to the auxiliary interconnection lines SU_BL via the auxiliary interconnection line contact plugs 343 disposed on the protruding portions.

In some example embodiments, by connecting the vertical pillars PL to the upper bit lines U_BL via the auxiliary interconnection lines SU_BL, adjacent upper bit lines U_BL may be disposed to be closer to each other. In other words, a pitch of lower bit lines D_BL formed in a second interlayer insulating film 112 may be greater than a pitch of the upper bit lines U_BL.

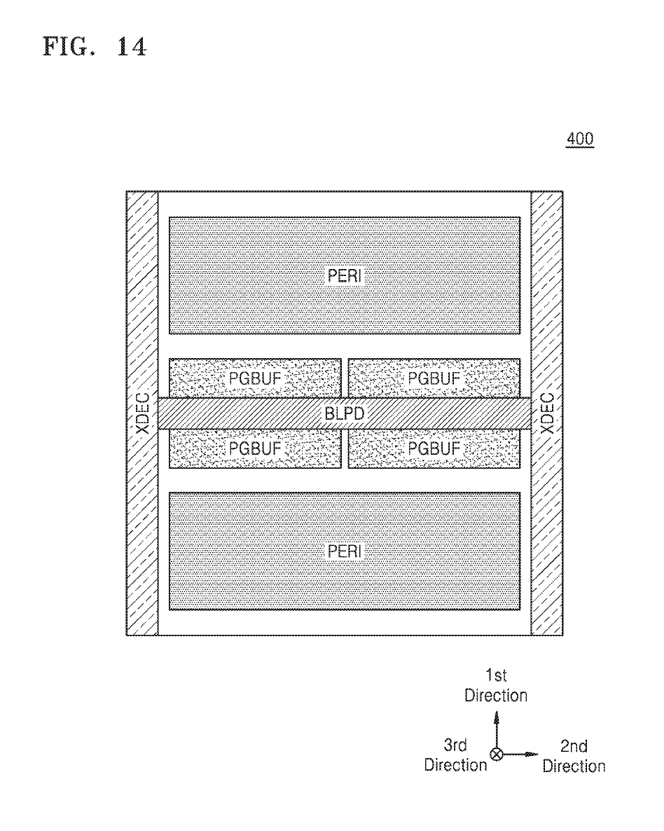

FIG. 14 is a diagram illustrating a configuration of circuits formed under a memory cell array (not shown) in a memory device 400 having a COP structure, according to some example embodiments of inventive concepts.

Page buffer circuits PGBUF, a row decoder XDEC, peripheral circuits PERI, and a bit line pad region BLPD may overlap a memory cell array (not shown) in the third direction. The peripheral circuits PERI may include a column logic, an internal voltage generator, a high voltage generator, a pre-decoder, a temperature sensor, a command decoder, an address decoder, a moving zone controller, a scheduler, and a test/measurement circuit, but is not limited thereto.

The row decoder XDEC may extend in a first direction and be disposed under both sides of the memory cell array (not shown). Although not illustrated in FIG. 14, the first direction may be a direction in which a plurality of word lines are arranged, for example, a direction perpendicular to a direction in which the word lines extend.

The bit line pad region BLPD, in which a plurality of connection regions where a conductive path between upper bit lines U_BL (refer to FIGS. 6 and 7) and lower bit lines D_BL (refer to FIGS. 6 and 7) is formed are positioned, may be formed in the center of the memory cell array (not shown) in a second direction. The second direction may be a direction in which a plurality of bit lines are arranged, for example, a direction perpendicular to a direction in which the bit lines extend.

The page buffer circuits PGBUF may be formed at both sides of the bit line pad region BLPD in the second direction. The page buffer circuits PGBUF may be electrically connected to the lower bit lines D_BL (refer to FIGS. 6 and 7) and/or the peripheral circuits PERI. As the page buffer circuits PGBUF are formed adjacent to the both sides of the bit line pad region BLPD, a bit line loading may be reduced.

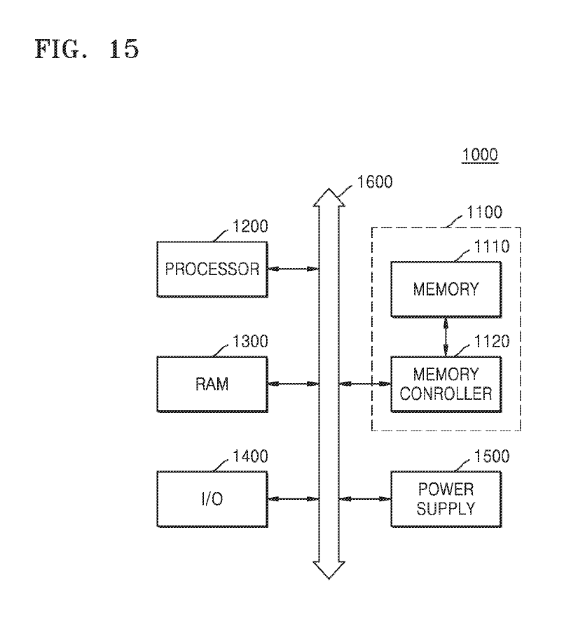

FIG. 15 is a block diagram of a computing system 1000 including a memory system 1100 according to some example embodiments of inventive concepts.

Referring to FIG. 15, the computing system 1000 may include a memory system 1100, a processor 1200, RAM 1300, an input/output (I/O) device 1400, and a power supply 1500. Although not illustrated in FIG. 15, the computing system 1000 may further include ports capable of communicating with a video card, a sound card, a memory card, a USB device, or other electronic devices. The computing system 1000 may be implemented with a personal computer or a portable electronic device such as a notebook computer, a mobile phone, a personal digital assistant (PDA), and a camera.

The processor 1200 may perform particular calculations or tasks. According to some example embodiments of inventive concepts, the processor 1200 may be a micro-processor or a central processing unit CPU. The processor 1200 may communicate with the RAM 1300, the I/0 device 1400, and the memory system 1100 via a bus 2600, such as an address bus, a control but, and a data bus. The memory system 1100 may be implemented by using example embodiments illustrated in FIGS. 1 to 14. A memory device having a layout according to some example embodiments of inventive concepts described with reference to FIGS. 1 to 14 may be applied to the memory system 1100. According to some example embodiments of inventive concepts, the processor 1200 may be connected to an expansion bus such as a peripheral component interconnect (PCI) bus.

The RAM 1300 may store data used for the operation of the computing system 1000. For example, the RAM 1300 may be implemented with DRAM, mobile DRAM, SRAM, PRAM, FRAM, RRAM, and/or MRAM.

The input/output device 1400 may include an input device such as a keyboard, a keypad, or a mouse, and an output device such as a printer or a display. The power supply 1500 may supply an operating voltage needed for the operation of the computing system 1000.

While some example embodiments of inventive concepts been particularly shown and described, it will be understood that various changes in form and details may be made therein without departing from the spirit and scope of the following claims.

1. A memory device comprising:
a first semiconductor layer including a plurality of lower bit lines that extend in a first direction and are parallel to each other in a second direction perpendicular to the first direction, the first semiconductor layer including a substrate;
a second semiconductor layer on the first semiconductor layer, the second semiconductor layer including a plurality of vertical pillars extending in a third direction that is perpendicular to the first and second directions; and
a plurality of upper bit lines connected to the plurality of vertical pillars and extending in the first direction on the first semiconductor layer,
the plurality of upper bit lines are arranged to have a first pitch in the second direction, the plurality of lower bit lines are arranged to have a second pitch in the second direction, and the first pitch and the second pitch have different lengths.

2. The memory device of claim 1, wherein the second pitch is greater than the first pitch.

3. The memory device of claim 1, wherein
the first semiconductor layer includes a plurality of page buffer circuits,
a first portion of the plurality of page buffer circuits are in a first page buffer group, and
a second portion of the plurality of page buffer circuits are in a second page buffer group.

4. The memory device of claim 3, wherein
a first lower bit line group includes some of the plurality of lower bit lines,
a second lower bit line group includes other ones of the plurality of lower bit lines,
the lower bit lines of the first lower bit line group are connected to page buffer circuits of the first page buffer group, and
the lower bit lines of the second lower bit line group are connected to page buffer circuits of the second page buffer group.

5. The memory device of claim 4, wherein the lower bit lines of the first lower bit line group and the lower bit lines of the second lower bit line group are alternately arranged in the second direction.

6. The memory device of claim 1, further comprising:
a plurality of gate electrodes stacked on top of each other along sidewalls of the plurality of vertical pillars;
a plurality of insulating films between the plurality of gate electrodes; and
a charge storage layer extending between the plurality of gate electrodes and the plurality of insulating films or extending between the plurality of gate electrodes and the plurality of vertical pillars.

7. The memory device of claim 1, further comprising:
a plurality of contact plugs penetrating through the second semiconductor layer in the third direction, wherein
the plurality of upper bit lines are respectively connected to the plurality of lower bit lines via some of the plurality of contact plugs.

8. The memory device of claim 7, further comprising:
a plurality of upper bit line contact plugs that connect the plurality of upper bit lines to some of the plurality of contact plugs; and
a plurality of lower bit line pads that connect the plurality of lower bit lines to some of the plurality of contact plugs.

9. The memory device of claim 8, wherein
the first semiconductor layer includes a plurality of page buffer circuits,
the plurality of upper bit line contact plugs and the plurality of lower bit line pads are arranged in the second direction and form a pad region, and
the plurality of page buffer circuits are adjacent to both sides of the pad region in the second direction.

10. The memory device of claim 1, wherein the plurality of vertical pillars of adjacent rows or columns are arranged in a honeycomb pattern.

11. The memory device of claim 1, further comprising:
a plurality of selection lines coupled to the plurality of vertical pillars and extending in the second direction; and
a plurality of auxiliary interconnection lines that connect at least two vertical pillars, coupled to different selection lines from among the plurality of vertical pillars, to each other,
wherein the plurality of upper bit lines are connected to the plurality of vertical pillars via the plurality of auxiliary interconnection lines.

12. A memory device comprising:
a first semiconductor layer including a plurality of lower bit lines extending in a first direction and arranged in a second direction perpendicular to the first direction, the first semiconductor layer including a substrate;
a plurality of page buffer circuits in the first semiconductor layer and arranged in a plurality of groups;
a second semiconductor layer on the first semiconductor layer in a third direction perpendicular to the first and second directions, the second semiconductor layer including a plurality of vertical pillars and a plurality of gate structures, the plurality of gate structures including a plurality of gate conductive layers stacked along sidewalls of the plurality of vertical pillars; and
a plurality of upper bit lines connected to the plurality of vertical pillars, the plurality of upper bit lines extending in the first direction on the plurality of gate structures and arranged in the second direction,
the plurality of upper bit lines are arranged to have a first pitch, the plurality of lower bit lines are arranged to have a second pitch, and the second pitch is greater than the first pitch.

13. The memory device of claim 12, further comprising:
a plurality of contact plugs connected to the plurality of upper bit lines and penetrating through the plurality of gate structures in the third direction, wherein
first ends of the plurality of lower bit lines are respectively connected to the plurality of page buffer circuits, and
second ends of the plurality of lower bit lines are respectively connected to the plurality of contact plugs.

14. The memory device of claim 12, wherein
the plurality of gate structures include a plurality of selection lines,
the memory device further includes a plurality of auxiliary interconnection lines that connect at least two vertical pillars, coupled to different selection lines from among the plurality of vertical pillars, to each other, and
the plurality of upper bit lines are connected to the plurality of vertical pillars via the plurality of auxiliary interconnection lines.

15. The memory device of claim 12, wherein
a first lower bit line group includes some of the plurality of lower bit lines,
a second lower bit line group includes other ones of the plurality of lower bit lines,
the first lower bit line group is connected to page buffer circuits of a first page buffer group among the plurality of page buffer circuits,
the second lower bit line group is connected to page buffer circuits of a second page buffer group among the plurality of page buffer circuits,
the first page buffer group is different from the second page buffer group.

16. A memory device comprising:
a substrate;
a plurality of lower bit lines on the substrate, the plurality of lower bit lines extending in a first direction and being spaced apart from each other by a first distance in a second direction, the second direction crossing the first direction;
a memory cell array on the substrate over the plurality of lower bit lines;
a plurality of word lines stacked on top of each other in a third direction crossing the first direction and the second direction, the plurality of word lines extending in the second direction and being connected to the memory cell array; and
a plurality of upper bit lines connected to the memory cell array, the plurality of upper bit lines crossing over the word lines and extending in the first direction,
the plurality of upper bit lines being spaced apart from each other in the second direction by a second distance that is less than the first distance.

17. The memory device of claim 16, wherein
the memory cell array includes a plurality of NAND strings connected to the plurality of word lines and the plurality of upper bit lines,
each of the NAND strings includes a plurality of memory cells stacked on top of each other on a ground selection transistor between the ground selection transistor and a string selection transistor, p1 the plurality of upper bit lines are connected to the string selection transistors of the plurality of NAND strings,
the plurality of upper bit lines have a first pitch, and
the plurality of lower bit lines have a second pitch that is greater than the first pitch.

18. The memory device of claim 16, further comprising:
a first semiconductor layer, wherein
the first semiconductor layer includes the plurality of lower bit lines and a plurality of page buffer circuits,
a first portion of the plurality of page buffer circuits are a first page buffer group,
a second portion of the plurality of page buffer circuits are a second page buffer group, a first group of the plurality of lower bit lines are connected to the page buffer circuits of the first page buffer group, and
a second group of the plurality of lower bit lines are connected to the page buffer circuits of the second page buffer group.

19. The memory device of claim 16, further comprising:
a plurality of contact plugs, wherein
the plurality of upper bit lines are connected to the plurality of lower bit lines via some of the plurality of contact plugs.

20. The memory device of claim 16, further comprising:
a plurality of transistors electrically connected to the plurality of lower bit lines, wherein
the memory cell array is over the plurality of transistors.
